(19) United States
(12) Patent Application Publication
(10) Pub. No.: US 2024/0113688 A1
(43) Pub. Date: Apr. 4, 2024

(54) Vibrator Element

(71) Applicant: SEIKO EPSON CORPORATION, Tokyo (JP)

(72) Inventor: Osamu KAWAUCHI, Shiojiri (JP)

(21) Appl. No.: 18/476,529

(22) Filed: Sep. 28, 2023

(30) Foreign Application Priority Data
Sep. 30, 2022 (JP) 2022-157659

(51) Int. Cl. H03H 9/19; H03H 3/02; H03H 9/05; H03H 9/10

(52) U.S. Cl. CPC H03H 9/19; H03H 3/02; H03H 9/0561; H03H 9/1035; H03H 2003/023

(57) ABSTRACT

A vibrator element includes: a plate-shaped vibrating substrate including a first surface and a second surface, which are in a front and back relationship, and including a vibrating portion, a support portion, and a coupling portion that couples the vibrating portion to the support portion and includes a portion having a thickness smaller than that of the support portion; an electrode layer including a first excitation electrode disposed at the first surface at the vibrating portion, a second excitation electrode disposed at the second surface at the vibrating portion, a first pad electrode disposed at the support portion, a second pad electrode disposed at the support portion, a first coupling electrode disposed at the coupling portion and coupling the first excitation electrode to the first pad electrode, and a second coupling electrode disposed at the coupling portion and coupling the second excitation electrode to the second pad electrode; a first metal film disposed at an upper layer on the first coupling electrode that is located on the coupling portion and having a thickness larger than that of the electrode layer; and a second metal film disposed at an upper layer on the second coupling electrode that is located on the coupling portion and having a thickness larger than that of the electrode layer.

The present application is based on, and claims priority from JP Application Serial Number 2022-157659, filed on Sep. 30, 2022, the disclosure of which is hereby incorporated by reference herein in its entirety.

### BACKGROUND

### 1. Technical Field

The present disclosure relates to a vibrator element.

### 2. Related Art

A vibrator element disclosed in JP-A-2020-141317 includes a vibrating substrate and an electrode disposed at the vibrating substrate. The vibrating substrate includes a vibrating portion, a support portion supporting the vibrating portion, and a coupling portion coupling the vibrating portion to the support portion, and the coupling portion is thinner than the support portion and the vibrating portion. Such a vibrator element is fixed to a fixing object such as a package at the support portion.

However, in the vibrator element disclosed in JP-A-2020-141317, since the coupling portion is thinner than the support portion and the vibrating portion, the coupling portion may be easily damaged by an external impact or the like.

### SUMMARY

A vibrator element according to the disclosure includes: a plate-shaped vibrating substrate including a first surface and a second surface, which are in a front and back relationship, and including a vibrating portion, a support portion, and a coupling portion that couples the vibrating portion to the support portion and includes a portion having a thickness smaller than that of the support portion; an electrode layer including a first excitation electrode disposed at the first surface at the vibrating portion, a second excitation electrode disposed at the second surface at the vibrating portion, a first pad electrode disposed at the support portion, a second pad electrode disposed at the support portion, a first coupling electrode disposed at the coupling portion and coupling the first excitation electrode to the first pad electrode, and a second coupling electrode disposed at the coupling portion and coupling the second excitation electrode to the second pad electrode; a first metal film disposed at an upper layer on the first coupling electrode that is located on the coupling portion and having a thickness larger than that of the electrode layer; and a second metal film disposed at an upper layer on the second coupling electrode that is located on the coupling portion and having a thickness larger than that of the electrode layer.

### BRIEF DESCRIPTION OF THE DRAWINGS

FIG. 1 is a cross-sectional view showing a vibrator according to a first embodiment of the disclosure.

FIG. 2 is a top view showing a vibrator element provided in the vibrator in FIG. 1.

FIG. 3 is a perspective view of the vibrator element.

FIG. 4 is a cross-sectional view taken along a line A-A in FIG. 2.

FIG. 5 is a cross-sectional view taken along a line B-B in FIG. 2.

FIG. 6 is a top view of the vibrator element, in which a metal film is not shown.

FIG. 7 is a top view showing a modification of the vibrator element.

FIG. 8 is a top view showing a modification of the vibrator element.

FIG. 9 is a top view showing a modification of the vibrator element.

FIG. 10 is a top view showing a modification of the vibrator element.

FIG. 11 is a cross-sectional view showing a method for manufacturing the vibrator element.

FIG. 12 is a cross-sectional view showing the method for manufacturing the vibrator element.

FIG. 13 is a cross-sectional view showing the method for manufacturing the vibrator element.

FIG. 14 is a cross-sectional view showing the method for manufacturing the vibrator element.

FIG. 15 is a cross-sectional view showing the method for manufacturing the vibrator element.

FIG. 16 is a cross-sectional view showing the method for manufacturing the vibrator element.

FIG. 17 is a cross-sectional view showing a vibrator element according to a second embodiment of the disclosure.

FIG. 18 is a cross-sectional view showing the vibrator element according to the second embodiment of the disclosure.

FIG. 19 is a cross-sectional view showing a vibrator element according to a third embodiment of the disclosure.

FIG. 20 is a cross-sectional view showing the vibrator element according to the third embodiment of the disclosure.

FIG. 21 is a plan view showing a vibrator element according to a fourth embodiment of the disclosure.

### DESCRIPTION OF EMBODIMENTS

Hereinafter, a vibrator element according to the disclosure will be described in detail based on embodiments shown in the accompanying drawings.

### First Embodiment

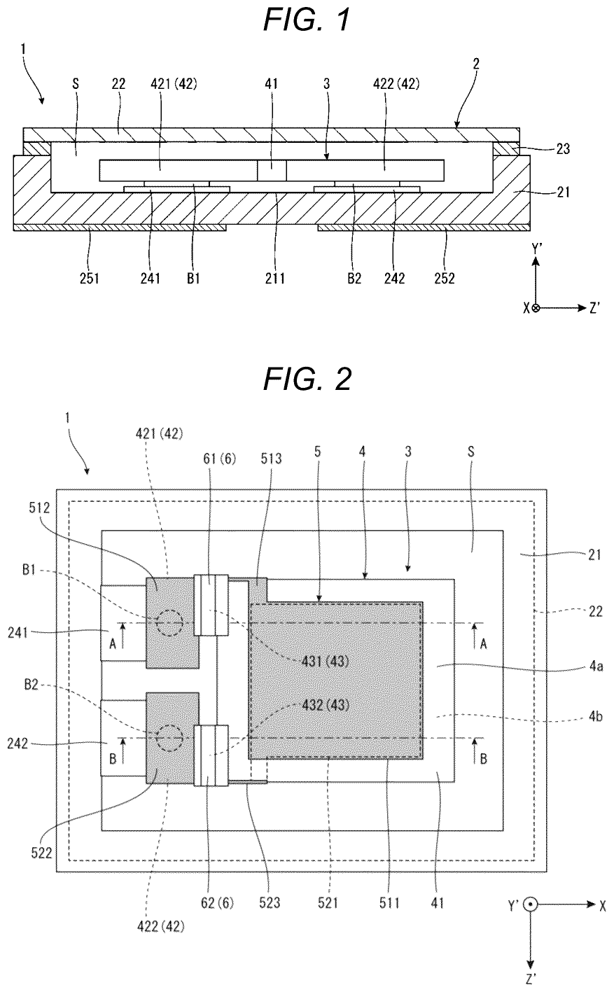

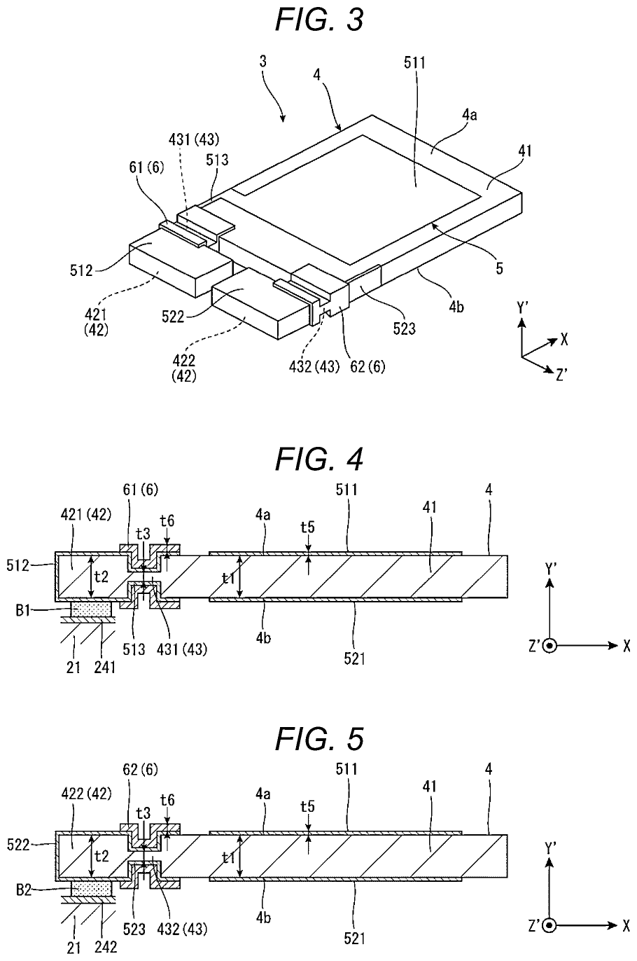

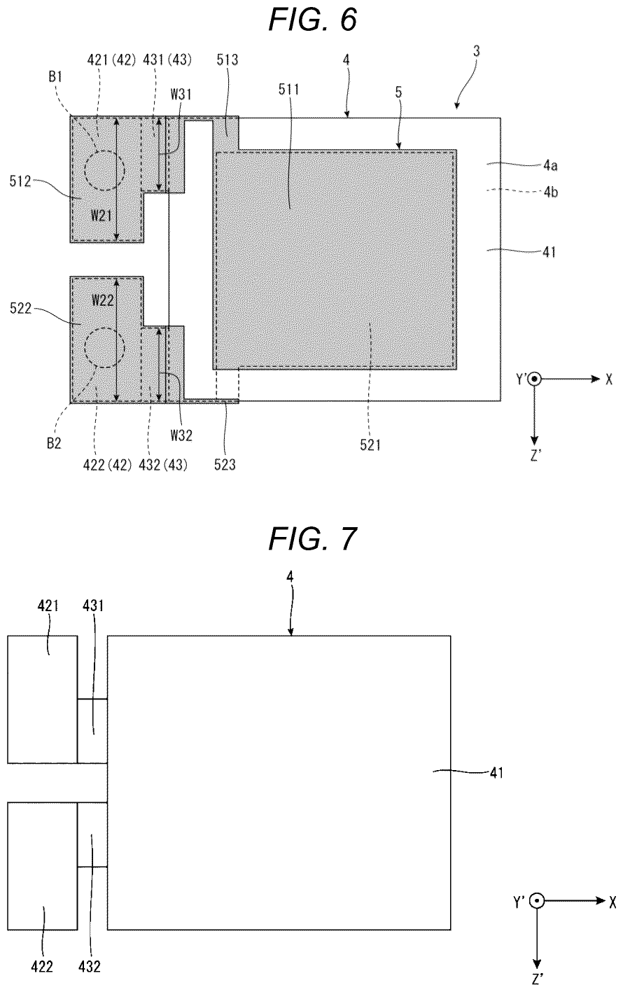

FIG. 1 is a cross-sectional view showing a vibrator according to a first embodiment of the disclosure. FIG. 2 is a top view showing a vibrator element provided in the vibrator in FIG. 1. FIG. 3 is a perspective view of the vibrator element. FIG. 4 is a cross-sectional view taken along a line A-A in FIG. 2. FIG. 5 is a cross-sectional view taken along a line B-B in FIG. 2. FIG. 6 is a top view of the vibrator element, in which a metal film is not shown. FIGS. 7 to 10 are top views showing modifications of the vibrator element. FIGS. 11 to 16 are cross-sectional views showing a method for manufacturing the vibrator element.

A vibrator 1 shown in FIG. 1 includes a package 2 and a vibrator element 3 accommodated in the package 2.

The package 2 includes a base 21 and a lid 22. The base 21 has a box shape and has a recess 211 that is open in an upper surface thereof. The vibrator element 3 is mounted on a bottom surface of the recess 211 by joining members B1 and B2. In addition, the lid 22 has a plate shape and is joined to the upper surface of the base 21 via a sealing member 23 such as a seal ring or low-melting-point glass so as to close an opening of the recess 211. Accordingly, the recess 211 is hermetically sealed, and an accommodating space S is formed inside the package 2. The accommodating space S is airtight and is in a depressurized state, preferably in a vacuum or a state close thereto. Accordingly, viscous resistance is reduced, and oscillation characteristics of the vibrator element 3 are improved.

Materials forming the base 21 and the lid 22 are not particularly limited. For example, the base 21 may be made of various ceramic materials such as alumina and titania, and the lid 22 may be made of various metal materials such as Kovar. Accordingly, a difference in linear expansion coefficient between the base 21 and the lid 22 is reduced, and the package 2 is less likely to generate thermal stress.

A pair of internal terminals 241 and 242 are disposed at the bottom surface of the recess 211, and a pair of external terminals 251 and 252 are disposed at a lower surface of the base 21. The internal terminal 241 is electrically coupled to the external terminal 251 via an internal wiring (not shown) formed in the base 21. Similarly, the internal terminal 242 is electrically coupled to the external terminal 252 via the internal wiring. The internal terminal 241 is electrically coupled to the vibrator element 3 via a conductive joining member B1, and the internal terminal 242 is electrically coupled to the vibrator element 3 via a conductive joining member B2.

The joining members B1 and B2 are not particularly limited as long as the joining members B1 and B2 have both conductivity and joining property, and can use, for example, various metal bumps such as gold bumps, silver bumps, copper bumps, and solder bumps, and conductive adhesives obtained by dispersing conductive fillers such as silver fillers in various conductive pastes such as silver pastes and copper pastes, and various polyimide-based, epoxy-based, silicone-based, and acrylic-based adhesives. When the former metal bumps are used as the joining members B1 and B2, generation of gas from the joining members B1 and B2 can be prevented, and an environmental change in the accommodating space S, particularly an increase in pressure, can be effectively prevented. Since the joining members B1 and B2 do not get wet and spread, the joining members B1 and B2 can be arranged at a narrow pitch, and a size of the vibrator 1 can be reduced. When the latter conductive adhesives are used as the joining members B1 and B2, the joining members B1 and B2 are softer than the metal bumps, and stress is less likely to be transmitted to the vibrator element 3.

As shown in FIGS. 2 and 3, the vibrator element 3 includes a vibrating substrate 4 that is an AT cut quartz crystal substrate, and an electrode layer 5 and a metal film 6 disposed at the vibrating substrate 4. The AT cut quartz crystal substrate has a thickness-shear vibration mode and a cubic frequency-temperature characteristic. Therefore, the vibrator element 3 has excellent temperature characteristics. However, a cut angle of the vibrating substrate 4 is not particularly limited.

Briefly describing the AT cut quartz crystal substrate, the quartz crystal substrate has crystal axes X, Y, and Z orthogonal to one another. The X axis, the Y axis, and the Z axis are referred to as an electrical axis, a mechanical axis, and an optical axis, respectively. The AT cut quartz crystal substrate is a “rotated Y-cut quartz crystal substrate” cut along a plane obtained by rotating an X-Z plane by a predetermined angle θ around the X axis, and a substrate cut along a plane obtained by rotating by θ=35° 15′ is referred to as an “AT cut quartz crystal substrate”. Hereinafter, the Y axis and the Z axis rotated around the X axis corresponding to the angle θ are referred to as a Y′ axis and a Z′ axis. That is, the quartz crystal substrate has a thickness in a Y′-axis direction and a spread in an X-Z′ plane direction. Hereinafter, an arrow tip end side of each axis is also referred to as a “plus side”, and an opposite side is also referred to as a “minus side”.

The vibrating substrate 4 has a plate shape and includes an upper surface 4a as a first surface and a lower surface 4b as a second surface, which are in a front and back relationship. The vibrating substrate 4 has a rectangular shape in a plan view, particularly a rectangular shape whose longitudinal direction is an X-axis direction. However, a shape of the vibrating substrate 4 in the plan view is not particularly limited, and may be, for example, a square shape or a shape other than a rectangular shape such as a circular shape or an elliptical shape. The vibrating substrate 4 includes a vibrating portion 41, a support portion 42 supporting the vibrating portion 41, and a coupling portion 43 located between the vibrating portion 41 and the support portion 42 and coupling the vibrating portion 41 to the support portion 42. The support portion 42 is located on a minus side in the X-axis direction of the vibrating portion 41. As shown in FIG. 2, such a vibrator element 3 is fixed to the base 21 at the support portion 42 via the joining members B1 and B2.

The vibrating portion 41 has a uniform thickness as a whole in the embodiment, but the disclosure is not limited thereto, and the vibrating portion 41 may be of a so-called “mesa type” or “inverted mesa type”.

The support portion 42 and the vibrating portion 41 have the same thickness. However, the coupling portion 43 is thinner than the support portion 42. That is, as shown in FIGS. 4 and 5, t3<t1 and t3<t2, in which a thickness of the vibrating portion 41 is t1, a thickness of the support portion 42 is t2, and a thickness of the coupling portion 43 is t3. Accordingly, the coupling portion 43 is the thinnest portion in the vibrating substrate 4. Therefore, the coupling portion 43 is easily deformed, and stress applied from the base 21, particularly thermal stress caused by a difference in linear expansion coefficient between the base 21 and the vibrating substrate 4, can be effectively absorbed and relaxed. Therefore, the stress is less likely to be transmitted to the vibrating portion 41, and a change in vibration characteristics can be effectively prevented. Therefore, the vibrator element 3 having excellent vibration characteristics is obtained.

Although t1 and t2 are not particularly limited and vary depending on a frequency of the vibrator element 3, t1 and t2 may be, for example, about 30 μm or more and 100 μm or less. Although t3 is not particularly limited and varies depending on a dimension and the like of the vibrating portion 41, t3 is, for example, preferably about 5 μm or more and 15 μm or less, and more preferably about 10 μm. Accordingly, the coupling portion 43 is sufficiently soft, and the stress from the base 21 can be more effectively absorbed and relaxed. The entire coupling portion 43 is thinner than the support portion 42 and the vibrating portion 41 in the embodiment, but the disclosure is not limited thereto, and at least a part of the coupling portion 43 may be thinner than the support portion 42 and the vibrating portion 41.

The coupling portion 43 is formed to be recessed on both upper and lower sides. That is, the upper surface 4a at the coupling portion 43 is located below the upper surface 4a at the support portion 42, and the lower surface 4b at the coupling portion 43 is located above the lower surface 4b at the support portion 42. A thickness center of the coupling portion 43 and thickness centers of the support portion 42 and the vibrating portion 41 are located on the same X-Z′ plane. Therefore, the vibrating substrate 4 has an upper-lower symmetrical shape. Accordingly, since the vibrator element 3 can be mounted on the base 21 in either an upper or lower direction, the vibrator 1 can be easily manufactured.

As shown in FIG. 6, the support portion 42 is divided into two parts, and includes a first support portion 421 and a second support portion 422, which are arranged side by side in a Z′-axis direction and are spaced apart from each other. The first and second support portions 421 and 422 are arranged symmetrically with respect to a center line passing through a center of the vibrating portion 41 and extending in the X-axis direction. The first support portion 421 is joined to the joining member B1, and the second support portion 422 is joined to the joining member B2. According to such a configuration, the coupling portion 43 is mainly deformed, and the first and second support portions 421 and 422 are spaced apart from each other or approach each other, whereby the stress applied from the base 21 can be more effectively absorbed and relaxed. Therefore, the stress from the base 21 is less likely to be transmitted to the vibrating portion 41, and the change in the vibration characteristics can be effectively prevented. Therefore, the vibrator element 3 having excellent vibration characteristics is obtained.

Similarly, the coupling portion 43 is divided into two parts, and includes a first coupling portion 431 and a second coupling portion 432, which are arranged side by side in the Z′-axis direction and are spaced apart from each other. The first coupling portion 431 couples the first support portion 421 to the vibrating portion 41, and the second coupling portion 432 couples the second support portion 422 to the vibrating portion 41. The first and second coupling portions 431 and 432 are arranged symmetrically with respect to the center line passing through the center of the vibrating portion 41 and extending in the X-axis direction. According to such a configuration, the coupling portion 43 is more easily deformed, and the first and second support portions 421 and 422 are easily spaced apart from each other or approach each other. Therefore, the stress applied from the base 21 can be more effectively absorbed and relaxed. Therefore, the stress from the base 21 is less likely to be transmitted to the vibrating portion 41, and the change in the vibration characteristics can be effectively prevented. Therefore, the vibrator element 3 having excellent vibration characteristics is obtained.

In particular, a width W31 of the first coupling portion 431 is smaller than a width W21 of the first support portion 421. That is, W31<W21. Similarly, a width W32 of the second coupling portion 432 is smaller than a width W22 of the second support portion 422. That is, W32<W22. Accordingly, the first and second coupling portions 431 and 432 corresponding to the base portions of the first and second support portions 421 and 422 are soft, and the first support portion 421 and the second support portion 422 are easily spaced apart from each other or approach each other. Therefore, the stress applied from the base 21 can be more effectively absorbed and relaxed. Therefore, the stress from the base 21 is less likely to be transmitted to the vibrating portion 41, and the change in the vibration characteristics can be effectively prevented. Therefore, the vibrator element 3 having excellent vibration characteristics is obtained.

As shown in FIGS. 3, 4, and 5, the electrode layer 5 includes a first excitation electrode 511 disposed at the upper surface 4a at the vibrating portion 41, a second excitation electrode 521 disposed at the lower surface 4b at the vibrating portion 41 to be opposite from the first excitation electrode 511, a first pad electrode 512 disposed at the first support portion 421, a second pad electrode 522 disposed at the second support portion 422, a first coupling electrode 513 electrically coupling the first excitation electrode 511 to the first pad electrode 512, and a second coupling electrode 523 electrically coupling the second excitation electrode 521 to the second pad electrode 522. The first pad electrode 512 is electrically coupled to the internal terminal 241 via the joining member B1, and the second pad electrode 522 is electrically coupled to the internal terminal 242 via the joining member B2. Accordingly, the package 2 and the vibrator element 3 are electrically coupled.

The first pad electrode 512 is formed at the entire surface of the first support portion 421, and the first coupling electrode 513 is formed at the entire surface of the first coupling portion 431. Similarly, the second pad electrode 522 is formed at the entire surface of the second support portion 422, and the second coupling electrode 523 is formed at the entire surface of the second coupling portion 432. However, arrangement of the first and second pad electrodes 512 and 522 and the first and second coupling electrodes 513 and 523 is not particularly limited.

Such an electrode layer 5 is formed by patterning a metal film formed at a surface of the vibrating substrate 4 using a photolithography technique and an etching technique. A configuration of the electrode layer 5 is not particularly limited as long as the electrode layer 5 has conductivity, and for example, the electrode layer 5 may include a laminate of a chromium (Cr) base layer and a gold (Au) surface layer. A thickness of the electrode layer 5 is not particularly limited, and is about 3000 Å.

As described above, in the vibrator element 3, the stress applied from the base 21 is absorbed and relaxed by making the coupling portion 43 thinner than the support portion 42 and the vibrating portion 41, but mechanical strength is reduced accordingly, and there is a risk of damage due to an impact. Therefore, the vibrator element 3 further includes the metal film 6 for reinforcing the coupling portion 43.

As shown in FIGS. 2 to 5, the metal film 6 includes a first metal film 61 disposed on the first coupling electrode 513 located on the first coupling portion 431 to reinforce the first coupling portion 431, and a second metal film 62 disposed on the second coupling electrode 523 located on the second coupling portion 432 to reinforce the second coupling portion 432. Accordingly, strength of the coupling portion 43 is increased, and impact resistance of the vibrator element 3 can be improved. By reducing the thickness of the coupling portion 43 and compensating for the insufficient strength with the first and second metal films 61 and 62, it is possible to increase tenacity of the coupling portion 43 and to achieve both absorption and relaxation of the stress and ensuring of the mechanical strength in a well-balanced manner.

In the embodiment, the metal film 6 is directly disposed on the first and second coupling electrodes 513 and 514 located on the first and second coupling portions 431 and 432, but the disclosure is not limited thereto. That is, the metal film 6 may be disposed at the first and second coupling electrodes 513 and 514 with another metal layer interposed therebetween. In other words, the metal film 6 may be disposed at upper layers on the first and second coupling electrodes 513 and 514 located on the first and second coupling portions 431 and 432.

The first metal film 61 covers the entire surface of the first coupling portion 431. Accordingly, the first coupling portion 431 can be effectively reinforced. The first metal film 61 is formed across the first coupling portion 431 and the first support portion 421. The first metal film 61 is formed across the first coupling portion 431 and the vibrating portion 41. Accordingly, a boundary portion between the first coupling portion 431 and the first support portion 421 and a boundary portion between the first coupling portion 431 and the vibrating portion 41, where stress is likely to concentrate, are covered with the first metal film 61, and mechanical strength of the portion is improved.

The second metal film 62 covers the entire surface of the second coupling portion 432. Accordingly, the second coupling portion 432 can be effectively reinforced. The second metal film 62 is formed across the second coupling portion 432 and the second support portion 422. The second metal film 62 is formed across the second coupling portion 432 and the vibrating portion 41. Accordingly, a boundary portion between the second coupling portion 432 and the second support portion 422 and a boundary portion between the second coupling portion 432 and the vibrating portion 41, where stress is likely to concentrate, are covered with the second metal film 62, and mechanical strength of the portion is improved.

A thickness t6 of the first and second metal films 61 and 62 is larger than a thickness t5 of the electrode layer 5. That is, t6>t5. The thicknesses t6 and t5 mean average thicknesses. Accordingly, the coupling portion 43 can be effectively reinforced by the first and second metal films 61 and 62. Although the thickness t6 is not particularly limited and varies depending on the dimension and the like of the vibrating substrate 4, t6 is, for example, preferably 5 μm or more and 50 μm or less. Accordingly, the first and second metal films 61 and 62 are sufficiently thick, and an effect of reinforcing the vibrating substrate 4 is more remarkable.

A material forming the first and second metal films 61 and 62 is not particularly limited, and uses nickel (Ni) in the embodiment. Accordingly, the first and second metal films 61 and 62 having high strength are obtained. By using a plating method, the first and second metal films 61 and 62 can be easily formed thick.

A configuration of the vibrator element 3 has been described above. However, the configuration of the vibrator element 3 is not particularly limited, and may be, for example, a configuration as shown in each of FIGS. 7 to 10. In FIGS. 7 to 10, the electrode layer 5 and the metal film 6 are not shown for convenience of description.

For example, in the embodiment, the first coupling portion 431 is biased toward an outer edge side of the vibrating substrate 4 with respect to the first support portion 421, and the second coupling portion 432 is biased toward an outer edge side of the vibrating substrate 4 with respect to the second support portion 422, but the disclosure is not limited thereto. As shown in FIG. 7, the first coupling portion 431 may be biased toward an inner side of the vibrating substrate 4 with respect to the first support portion 421, and the second coupling portion 432 may be biased toward an inner side of the vibrating substrate 4 with respect to the second support portion 422.

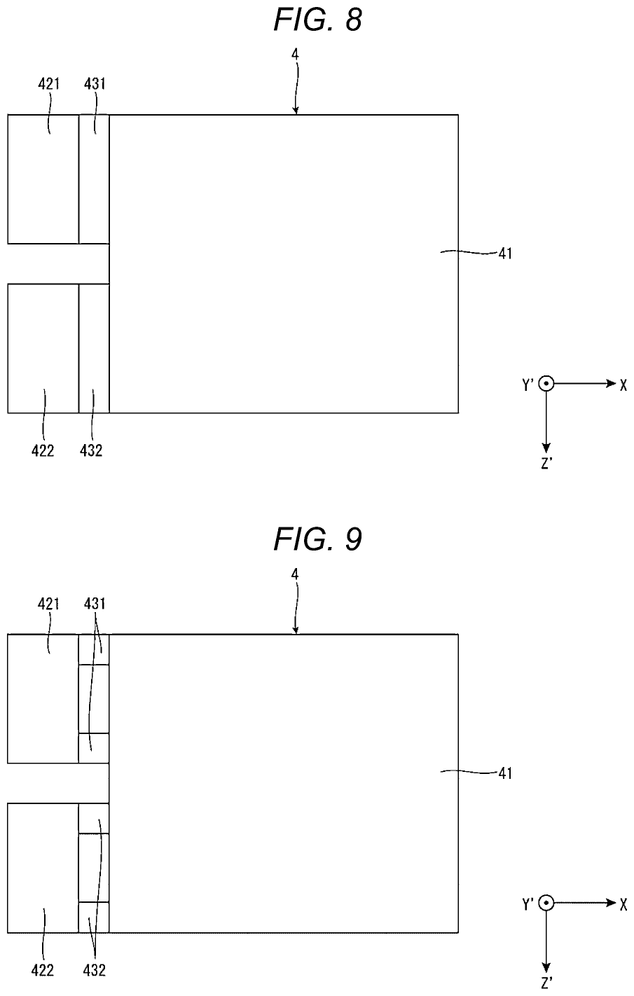

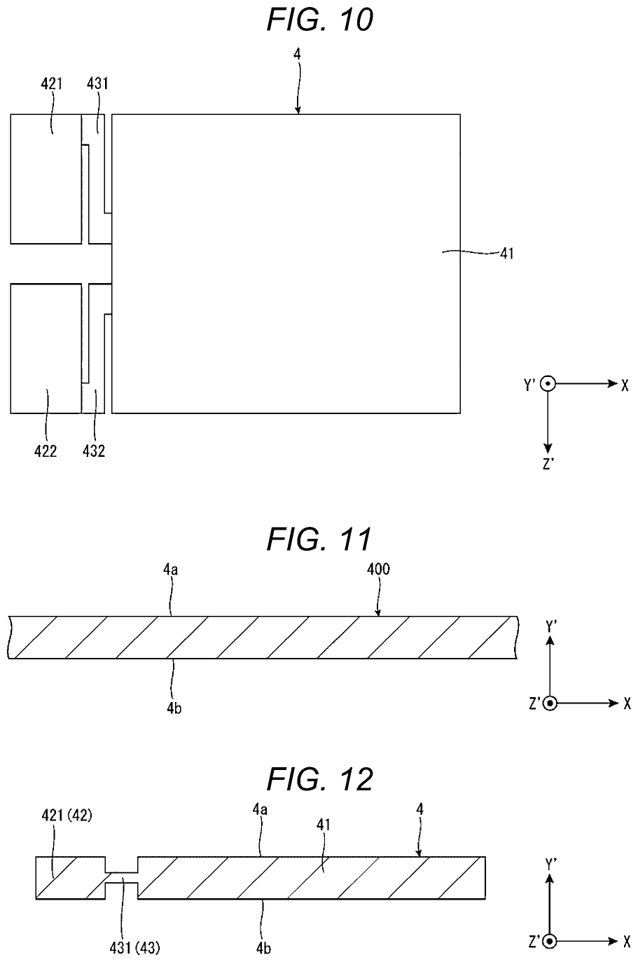

As shown in FIG. 8, a width of the first coupling portion 431 may be equal to a width of the first support portion 421, and a width of the second coupling portion 432 may be equal to a width of the second support portion 422. As shown in FIG. 9, a plurality of first coupling portions 431 may be formed side by side in the Z′-axis direction, and a plurality of second coupling portions 432 may be formed side by side in the Z′-axis direction. As shown in FIG. 10, the first and second coupling portions 431 and 432 may be bent or curved one or more times therealong.

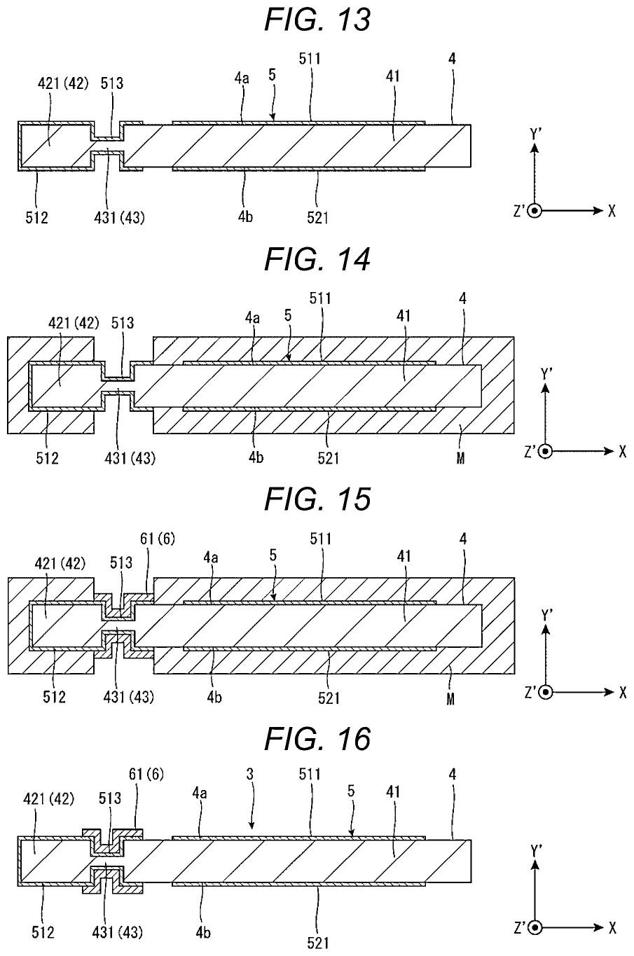

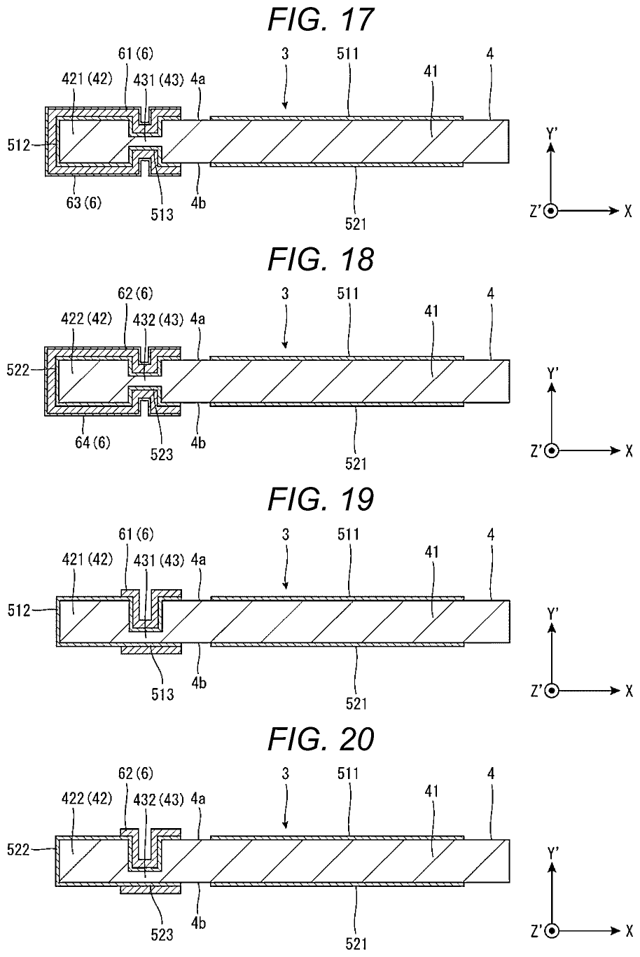

Next, a method for manufacturing the vibrator element 3 will be described. First, as shown in FIG. 11, an AT cut quartz crystal substrate 400 as a base material of the vibrating substrate 4 is prepared. The quartz crystal substrate 400 is larger than the vibrating substrate 4, and a plurality of vibrating substrates 4 can be formed from the quartz crystal substrate 400. Next, as shown in FIG. 12, the quartz crystal substrate 400 is patterned using the photolithography technique and the etching technique to form the vibrating substrate 4. Next, as shown in FIG. 13, the electrode layer 5 is formed at the vibrating substrate 4. The electrode layer 5 can be formed by forming a metal film on the surface of the vibrating substrate 4 and patterning the formed metal film using the photolithography technique and the etching technique. Next, as shown in FIG. 14, a mask M having openings in regions for forming the first and second metal films 61 and 62 is formed on the vibrating substrate 4. Next, as shown in FIG. 15, the metal film 6 is formed at the surface of the vibrating substrate 4 by electroless plating. Finally, as shown in FIG. 16, the mask M is removed. Accordingly, the vibrator element 3 is obtained. According to such a manufacturing method, the vibrator element 3 can be easily manufactured.

The vibrator 1 has been described above. As described above, the vibrator element 3 provided in the vibrator 1 includes: the plate-shaped vibrating substrate 4 including the upper surface 4a as a first surface and the lower surface 4b as a second surface, which are in a front and back relationship, and including the vibrating portion 41, the support portion 42, and the coupling portion 43 that couples the vibrating portion 41 to the support portion 42 and includes a portion having a thickness smaller than that of the support portion 42; the electrode layer 5 including the first excitation electrode 511 disposed at the upper surface 4a at the vibrating portion 41, the second excitation electrode 521 disposed at the lower surface 4b at the vibrating portion 41, the first pad electrode 512 disposed at the support portion 42, the second pad electrode 522 disposed at the support portion 42, the first coupling electrode 513 disposed at the coupling portion 43 and coupling the first excitation electrode 511 to the first pad electrode 512, and the second coupling electrode 523 disposed at the coupling portion 43 and coupling the second excitation electrode 521 to the second pad electrode 522; the first metal film 61 disposed at an upper layer on the first coupling electrode 513 that is located on the coupling portion 43 and having a thickness larger than that of the electrode layer 5, and the second metal film 62 disposed at an upper layer on the second coupling electrode 523 that is located on the coupling portion 43 and having a thickness larger than that of the electrode layer 5. According to such a configuration, the coupling portion 43 is easily deformed, and stress applied from the base 21 can be effectively absorbed and relaxed. Therefore, the stress is less likely to be transmitted to the vibrating portion 41, and a change in vibration characteristics due to the stress can be effectively prevented. Therefore, the vibrator element 3 having excellent vibration characteristics is obtained. Further, by disposing the first and second metal films 61 and 62 at the coupling portion 43, the coupling portion 43 is reinforced, and the vibrator element 3 having excellent impact resistance is obtained.

As described above, each of the first metal film 61 and the second metal film 62 is disposed across the coupling portion 43 and the support portion 42. With such a configuration, a boundary portion between the coupling portion 43 and the support portion 42 where stress is likely to concentrate is covered with the first and second metal films 61 and 62, and mechanical strength of the portion is improved.

As described above, each of the first metal film 61 and the second metal film 62 is disposed across the coupling portion 43 and the vibrating portion 41. With such a configuration, a boundary portion between the coupling portion 43 and the vibrating portion 41 where stress is likely to concentrate is covered with the first and second metal films 61 and 62, and mechanical strength of the portion is improved.

As described above, the coupling portion 43 includes a portion having a thickness smaller than that of the vibrating portion 41. According to such a configuration, the coupling portion 43 is easily deformed, and stress applied from the base 21 can be effectively absorbed and relaxed. Therefore, the stress is less likely to be transmitted to the vibrating portion 41, and a change in vibration characteristics due to the stress can be effectively prevented.

As described above, the support portion 42 includes the first support portion 421 and the second support portion 422, which are spaced apart from each other, the first pad electrode 512 is disposed at the first support portion 421, and the second pad electrode 522 is disposed at the second support portion 422. Accordingly, the first and second support portions 421 and 422 are spaced apart from each other or approach each other, whereby stress applied from the base 21 can be more effectively absorbed or relaxed. Therefore, the stress from the base 21 is less likely to be transmitted to the vibrating portion 41, and the change in the vibration characteristics can be effectively prevented.

As described above, the coupling portion 43 includes the first coupling portion 431 coupling the first support portion 421 to the vibrating portion 41 and the second coupling portion 432 coupling the second support portion 422 to the vibrating portion 41. Accordingly, the coupling portion 43 is easily deformed, and the first and second support portions 421 and 422 are easily spaced apart from each other or approach each other. Therefore, the stress applied from the base 21 can be more effectively absorbed and relaxed.

As described above, the first coupling portion 431 is narrower than the first support portion 421, and the second coupling portion 432 is narrower than the second support portion 422. Accordingly, the first and second coupling portions 431 and 432 are softer, and the first support portion 421 and the second support portion 422 are more likely to be spaced apart from each other or approach each other. Therefore, the stress applied from the base 21 can be more effectively absorbed and relaxed.

### Second Embodiment

FIGS. 17 and 18 are cross-sectional views showing a vibrator element according to a second embodiment of the disclosure. FIG. 17 is a cross-sectional view taken along the line A-A in FIG. 2, and FIG. 18 is a cross-sectional view taken along the line B-B in FIG. 2.

The vibrator element 3 according to the embodiment is similar to the vibrator element 3 according to the first embodiment described above except that the first metal film 61 and the second metal film 62 are further formed at all of the side surfaces and upper and lower surfaces of the first and second support portions 421 and 422, and a third metal film 63 and a fourth metal film 64 are provided. In the following description, regarding the vibrator element 3 according to the embodiment, differences from the first embodiment will be mainly described, and description of similar matters will be omitted. In the drawings of the embodiment, configurations similar to those according to the above embodiment will be denoted by the same reference numerals.

In the vibrator element 3 shown in FIGS. 17 and 18, the first metal film 61 is further formed at all of the side surface and upper and lower surfaces of the first support portion 421. Specifically, the first metal film 61 is formed at a side surface of the first support portion 421 located on a minus side in the X-axis direction, the upper surface 4a at the first support portion 421, and the lower surface 4b at the first support portion 421, with the first pad electrode 512 interposed therebetween.

In the vibrator element 3 shown in FIGS. 17 and 18, the second metal film 62 is formed at all of the side surface and upper and lower surfaces of the second support portion 422. Specifically, the second metal film 62 is formed at a side surface of the second support portion 422 located on the minus side in the X-axis direction, the upper surface 4a at the second support portion 422, and the lower surface 4b at the second support portion 422, with the second pad electrode 522 interposed therebetween.

The vibrator element 3 shown in FIGS. 17 and 18 includes the third metal film 63 disposed on the first metal film 61 and the fourth metal film 64 disposed on the second metal film 62. With this configuration, the support portion 42 can be more effectively reinforced. The third metal film 63 and the fourth metal film 64 are not particularly limited, and are made of Au (gold) in this embodiment. Accordingly, corrosion and oxidation of the first and second metal films 61 and 62 can be prevented. Compatibility with gold bumps used as the joining members B1 and B2 is good, and the vibrator element 3 can be more firmly joined to the base 21.

The third metal film 63 is directly disposed on the first metal film 61, and the fourth metal film 64 is directly disposed on the second metal film 62 in the embodiment, but the disclosure is not limited thereto. That is, the third metal film 63 may be disposed at the first metal film 61 with another metal layer interposed therebetween, and the fourth metal film 64 may be disposed at the second metal film 62 with another metal layer interposed therebetween. In other words, the third metal film 63 may be disposed at an upper layer on the first metal film 61, and the fourth metal film 64 may be disposed at an upper layer on the second metal film 62.

As described above, the vibrator element 3 according to the embodiment includes the third metal film 63 disposed at the upper layer on the first metal film 61 and the fourth metal film 64 disposed at the upper layer on the second metal film 62. Accordingly, the support portion 42 can be more effectively reinforced. In particular, when the third metal film 63 and the fourth metal film 64 are made of Au (gold), corrosion and oxidation of the first and second metal films 61 and 62 can be prevented. Compatibility with gold bumps used as the joining members B1 and B2 is good, and the vibrator element 3 can be more firmly joined to the base 21.

According to the second embodiment, the same effects as those according to the first embodiment can also be attained.

### Third Embodiment

FIGS. 19 and 20 are cross-sectional views showing a vibrator element according to a third embodiment of the disclosure. FIG. 19 is a cross-sectional view taken along the line A-A in FIG. 2, and FIG. 20 is a cross-sectional view taken along the line B-B in FIG. 2.

The vibrator element 3 according to the embodiment is similar to the vibrator element 3 according to the first embodiment described above except that a shape of the vibrating substrate 4 is different. In the following description, regarding the vibrator element 3 according to the embodiment, differences from the first embodiment will be mainly described, and description of similar matters will be omitted. In the drawings of the embodiment, configurations similar to those according to the above embodiment will be denoted by the same reference numerals.

In the vibrator element 3 according to the embodiment, the lower surface 4b at the coupling portion 43, the lower surface 4b at the support portion 42, and the lower surface 4b at the vibrating portion 41 are formed as a continuous flat surface. The first metal film 61 is disposed at the lower surface 4b at the first coupling portion 431, and the second metal film 62 is disposed at the lower surface 4b at the second coupling portion 432. With this configuration, the first and second metal films 61 and 62 can be formed before an outer shape of the vibrating substrate 4 is formed. Therefore, formation accuracy of the first and second metal films 61 and 62 is improved.

The first metal film 61 and the second metal film 62 are disposed at a part of the lower surface 4b at the first and second support portions 421 and 422, respectively, in the embodiment, but the disclosure is not limited thereto. That is, the first metal film 61 and the second metal film 62 may be disposed at the entire lower surface 4b at the first and second support portions 421 and 422. Accordingly, mechanical strength of a boundary portion between the first coupling portion 431 and the first support portion 421 and a boundary portion between the second coupling portion 432 and the second support portion 422, where stress is likely to concentrate, can be improved.

The first metal film 61 and the second metal film 62 are disposed at both the upper surface 4a and the lower surface 4b at the first and second coupling portions 431 and 432, respectively, in the vibrator element 3 shown in FIGS. 19 and 20, but the disclosure is not limited thereto. That is, the first metal film 61 and the second metal film 62 may be disposed at only one of the upper surface 4a and the lower surface 4b at the first and second coupling portions 431 and 432. In this case, the first metal film 61 and the second metal film 62 may be disposed at the entirety of one of the upper surface 4a and the lower surface 4b at the first and second support portions 421 and 422.

As described above, in the vibrator element 3 according to the embodiment, the lower surface 4b at the coupling portion 43, the lower surface 4b at the support portion 42, and the lower surface 4b at the vibrating portion 41 form the continuous flat surface, and the first metal film 61 and the second metal film 62 are disposed on a lower surface 4b side. Accordingly, the first and second metal films 61 and 62 can be formed before the outer shape of the vibrating substrate 4 is formed. Therefore, the formation accuracy of the first and second metal films 61 and 62 is improved.

According to the third embodiment, the same effects as those according to the first embodiment can be also attained.

### Fourth Embodiment

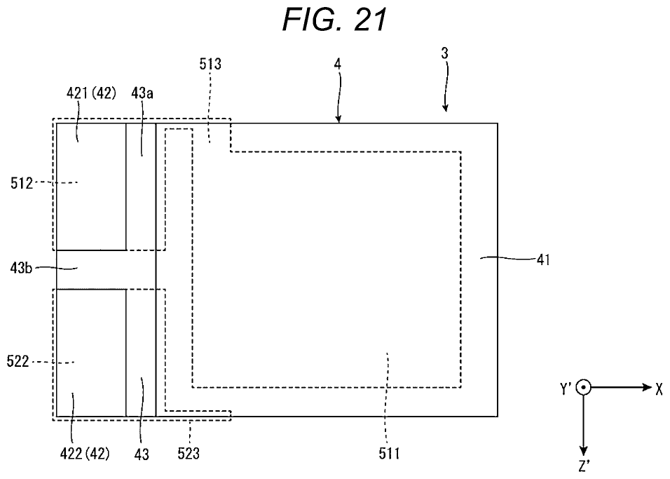

FIG. 21 is a plan view showing a vibrator element according to a fourth embodiment of the disclosure. In FIG. 21, the metal film 6 is not shown for convenience of description.

The vibrator element 3 according to the embodiment is similar to the vibrator element 3 according to the first embodiment described above except that a shape of the vibrating substrate 4, particularly a shape of the coupling portion 43, is different. In the following description, regarding the vibrator element 3 according to the embodiment, differences from the first embodiment will be mainly described, and description of similar matters will be omitted. In the drawings of the embodiment, configurations similar to those according to the above embodiment will be denoted by the same reference numerals.

In the vibrator element 3 shown in FIG. 21, the coupling portion 43 includes a first partition portion 43a located between the support portion 42 and the vibrating portion 41 and partitioning the support portion 42 and the vibrating portion 41, and a second partition portion 43b located between the first support portion 421 and the second support portion 422 and partitioning the first support portion 421 and the second support portion 422. The first partition portion 43a extends in the Z′-axis direction, and the second partition portion 43b extends in the X-axis direction and has one end coupled to the first partition portion 43a. Therefore, the coupling portion 43 has a T shape. According to such a configuration, although the first and second support portions 421 and 422 are less likely to approach each other or be spaced apart from each other, mechanical strength of the vibrating substrate 4 can be improved, as compared with a configuration according to the first embodiment described above.

As described above, in the vibrator element 3 according to the embodiment, the support portion 42 includes the first support portion 421 at which the first pad electrode 512 is disposed and the second support portion 422 at which the second pad electrode 522 is disposed, and the coupling portion 43 includes the first partition portion 43a located between the support portion 42 and the vibrating portion 41 and partitioning the support portion 42 and the vibrating portion 41, and a second partition portion 43b located between the first support portion 421 and the second support portion 422 and partitioning the first support portion 421 and the second support portion 422. According to such a configuration, although the first and second support portions 421 and 422 are less likely to approach each other or be spaced apart from each other, the mechanical strength of the vibrating substrate 4 can be improved, as compared with the configuration according to the first embodiment described above.

According to the fourth embodiment, the same effects as those according to the first embodiment can be also attained.

Although the vibrator element according to the disclosure has been described above based on the embodiments shown in the drawings, the disclosure is not limited thereto, and a configuration of each portion can be replaced with any configuration having the same function. Any other element may be added to the disclosure. The disclosure may be a combination of any two or more configurations in the embodiments.

In the above embodiment, the support portion 42 is divided into the first and second support portions 421 and 422, but the disclosure is not limited thereto. That is, the first and second pad electrodes 512 and 522 may be disposed together on one support portion 42.

In the above embodiment, the vibrator element 3 is applied to the vibrator 1, but the disclosure is not limited thereto, and the vibrator element 3 may be applied to an oscillator in which an oscillation circuit that oscillates the vibrator element 3 is mounted in the package 2.

What is claimed is:

1. A vibrator element comprising:
a plate-shaped vibrating substrate including a first surface and a second surface, which are in a front and back relationship, and including a vibrating portion, a support portion, and a coupling portion that couples the vibrating portion to the support portion and includes a portion having a thickness smaller than that of the support portion;
an electrode layer including a first excitation electrode disposed at the first surface at the vibrating portion, a second excitation electrode disposed at the second surface at the vibrating portion, a first pad electrode disposed at the support portion, a second pad electrode disposed at the support portion, a first coupling electrode disposed at the coupling portion and coupling the first excitation electrode to the first pad electrode, and a second coupling electrode disposed at the coupling portion and coupling the second excitation electrode to the second pad electrode;
a first metal film disposed at an upper layer on the first coupling electrode that is located on the coupling portion and having a thickness larger than that of the electrode layer; and
a second metal film disposed at an upper layer on the second coupling electrode that is located on the coupling portion and having a thickness larger than that of the electrode layer.

2. The vibrator element according to claim 1, wherein
the first metal film and the second metal film are disposed across the coupling portion and the support portion.

3. The vibrator element according to claim 2, wherein
the first metal film and the second metal film are disposed across the coupling portion and the vibrating portion.

4. The vibrator element according to claim 1, wherein
the coupling portion includes a portion having a thickness smaller than that of the vibrating portion.

5. The vibrator element according to claim 1, wherein
the support portion includes a first support portion at which the first pad electrode is disposed and a second support portion at which the second pad electrode is disposed, and
the coupling portion includes a first partition portion located between the support portion and the vibrating portion and partitioning the support portion and the vibrating portion, and a second partition portion located between the first support portion and the second support portion and partitioning the first support portion and the second support portion.

6. The vibrator element according to claim 1, wherein
the support portion includes a first support portion and a second support portion, which are spaced apart from each other,
the first pad electrode is disposed at the first support portion, and
the second pad electrode is disposed at the second support portion.

7. The vibrator element according to claim 6, wherein
the coupling portion includes a first coupling portion coupling the first support portion to the vibrating portion and a second coupling portion coupling the second support portion to the vibrating portion.

8. The vibrator element according to claim 7, wherein
the first coupling portion is narrower than the first support portion, and
the second coupling portion is narrower than the second support portion.

9. The vibrator element according to claim 1, wherein
the second surface at the coupling portion, the second surface at the support portion, and the second surface at the vibrating portion form a continuous flat surface, and
the first metal film and the second metal film are disposed on a second surface side.

10. The vibrator element according to claim 1, further comprising:
a third metal film disposed at an upper layer on the first metal film; and
a fourth metal film disposed at an upper layer on the second metal film.
